(19) United States
(12) Patent Application Publication
(10) Pub. No.: US 2015/0325525 A1
(43) Pub. Date: Nov. 12, 2015

(54) FORMING INTERCONNECT STRUCTURE WITH POLYMERIC LAYER AND RESULTING DEVICE

(71) Applicant: GLOBALFOUNDRIES INC., Grand Cayman (KY)

(72) Inventor: Sunil SINGH, Mechanicville, NY (US)

(73) Assignee: GLOBALFOUNDRIES INC., Grand Cayman (KY)

(21) Appl. No.: 14/273,237

(22) Filed: May 8, 2014

(51) Int. Cl. H01L 23/532; H01L 21/02; H01L 21/768

(52) U.S. Cl. CPC H01L 23/53295; H01L 21/76895; H01L 21/02118; H01L 21/0212; H01L 21/02167; H01L 21/02164

(57) ABSTRACT

Methods for forming an interconnect structure using a carbon-rich polymeric layer and the resulting devices are disclosed. Embodiments may include forming a carbon-rich polymeric layer above a semiconductor element, forming a silicon oxide material layer above the carbon-rich polymeric layer, and forming an interconnect through the silicon oxide material layer and the carbon-rich polymeric layer.

### TECHNICAL FIELD

The present disclosure relates to fabrication of interconnect structures, such as interconnects for flip-chip packaging. The present disclosure is particularly applicable to forming copper (Cu)/low-k interconnects in flip-chip packaging for 28 nanometer (nm) technology nodes and beyond.

### BACKGROUND

Chip-package interaction (CPI) has become a critical reliability issue for flip-chip packaging of interconnects, such as Cu/low-k interconnects. Thermo-mechanical deformation and stress commonly develop inside a package during assembly and in subsequent reliability testing due to the mismatch of the coefficients of thermal expansion (CTEs) between the chip and the substrate. The developed deformation and stress often cause mechanical reliability issues in solder joints and in underfill layers between die and substrate.

The reliability issues often include solder fatigue and/or failure as well as underfill delamination. Moreover, thermo-mechanical deformation of a package is often coupled directly into Cu/low-k interconnects, thus inducing large local stresses which often drive interfacial crack formation and propagation. The thermo-mechanical reliability risk is often further aggravated due to the implementation of ultra-low-k (ULK) dielectric materials, which are commonly utilized for better electrical performance. A low-k dielectric is defined as a material with a dielectric constant less than 3.9 (the dielectric constant of silicon dioxide), a ULK dielectric refers to a dielectric constant much smaller than 3.9, and a high-k dielectric is a material with a dielectric constant greater than 3.9. Implementation of ULK is often required due to mandated changes from lead (Pb)-containing to Pb-free solders for environmental safety.

A need therefore exists for methodology enabling formation of interconnect structures, and the resulting device, having improved CPI and reliability performance in interconnects, such as interconnects in flip-chip packaging.

### SUMMARY

An aspect of the present disclosure includes a method for forming an interconnect structure using a carbon-rich polymeric layer.

Another aspect of the present disclosure includes an interconnect structure including a carbon-rich polymeric layer.

Additional aspects and other features of the present disclosure will be set forth in the description which follows and, in part, may be apparent to those having ordinary skill in the art upon examination of the following or may be learned from the practice of the present disclosure. Advantages of the present disclosure may be realized and obtained as particularly pointed out in the appended claims.

According to the present disclosure, some technical effects may be achieved, in part, by a method including forming a carbon-rich polymeric layer above a semiconductor element, forming a silicon oxide material layer above the carbon-rich polymeric layer, and forming an interconnect through the silicon oxide material layer and the carbon-rich polymeric layer.

Another aspect includes forming a silicon carbide material layer above a semiconductor element prior to forming the carbon-rich polymeric layer. A further aspect includes forming a second carbon-rich polymeric layer above a semiconductor element prior to forming the interconnect. Another aspect includes a combined thickness of the two carbon-rich polymeric layers and the silicon oxide material layer being 1500 to 1600 nm. An additional aspect includes the two carbon-rich polymeric layers including one of polynorbornene, polybenzocyclobutene, polyimide, and polytetrafluoroethylene. Another aspect includes the two carbon-rich polymeric layers including polytetrafluoroethylene. A further aspect includes the silicon oxide material layer including tetraethyl orthosilicate. Another aspect includes the silicon oxide material layer including fluorine-doped tetraethyl orthosilicate. An additional aspect includes a thickness of each carbon-rich polymeric layer being 100 to 300 nm.

Another aspect includes a device including a carbon-rich polymeric layer above a semiconductor element. Another aspect includes a silicon oxide material layer above the carbon-rich polymeric layer. A further aspect includes an interconnect through the silicon oxide material layer and the carbon-rich polymeric layer. Another aspect includes a silicon carbide material layer above the semiconductor element and below the carbon-rich polymeric layer. An additional aspect includes a second carbon-rich polymeric layer above the semiconductor element. Another aspect includes a combined thickness of the two carbon-rich polymeric layers and the silicon oxide material layer being 1500 to 1600 nm. Another aspect includes the two carbon-rich polymeric layers including one of polynorbornene, polybenzocyclobutene, polyimide and polytetrafluoroethylene. An additional aspect includes the two carbon-rich polymeric layers including polytetrafluoroethylene. Another aspect includes the silicon oxide material layer including tetraethyl orthosilicate. Yet another aspect includes the silicon oxide material layer including fluorine-doped tetraethyl orthosilicate. Yet still another aspect includes a thickness of each carbon-rich polymeric layer being 50 to 500 nm.

Another aspect includes forming a silicon carbide material layer on a semiconductor element. A further aspect includes forming a first carbon-rich polymeric layer on the silicon carbide material layer. Another aspect includes forming a silicon oxide material layer on the first carbon-rich polymeric layer. An additional aspect includes forming a second carbon-rich polymeric layer on the silicon oxide material layer. Another aspect includes forming an interconnect through one or more of the silicon carbide material layer, the first carbon-rich polymeric layer, the silicon oxide material layer, and the second carbon-rich polymeric layer. A further aspect includes a combined thickness of the two carbon-rich polymeric layers and the silicon oxide material layer being 1500 to 1600 nm. Another aspect includes a thickness of each carbon-rich polymeric layer being 100 to 300 nm. Yet another aspect includes the two carbon-rich polymeric layers including polytetrafluoroethylene. Still yet another aspect includes the silicon oxide material layer including fluorine-doped tetraethyl orthosilicate.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIG. 1 schematically illustrates a semiconductor device, in accordance with an exemplary embodiment;

FIG. 2 schematically illustrates a process flow for making a semiconductor device, in accordance with an exemplary embodiment; and

FIG. 3 schematically illustrates a process flow for making a semiconductor device, in accordance with an alternative exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of reliability performance issues such as solder fatigue failure, underfill delamination, and interfacial cracks attendant upon CPI in flip-chip packaging of interconnects, such as Cu/low-k interconnects. The present disclosure also improves Fatwire metal Rs non-uniformity and Fatwire RC performance as carbon-rich polymeric material in the carbon-rich polymeric layer(s) has a lower dielectric constant than silicon oxide material in the silicon oxide material layer.

In accordance with embodiments of the present disclosure, a process uses a carbon-rich polymeric layer in forming an interconnect structure.

Methodology in accordance with embodiments of the present disclosure may include forming a carbon-rich polymeric layer above a semiconductor element, forming a silicon oxide material layer above the carbon-rich polymeric layer, and forming an interconnect through the silicon oxide material layer and the carbon-rich polymeric layer. According to an embodiment, the methodology may include forming a silicon carbide material layer above the semiconductor element prior to forming the carbon-rich polymeric layer. The methodology may further include forming a second carbon-rich polymeric layer above the semiconductor element prior to forming the interconnect.

Still other aspects, features, and technical effects will be readily apparent to those skilled in the art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

Although the examples below are focused on forming Cu/low-k interconnects, the process may be modified for forming interconnects utilizing other materials without changing the spirit and scope of the process and without any undue burden.

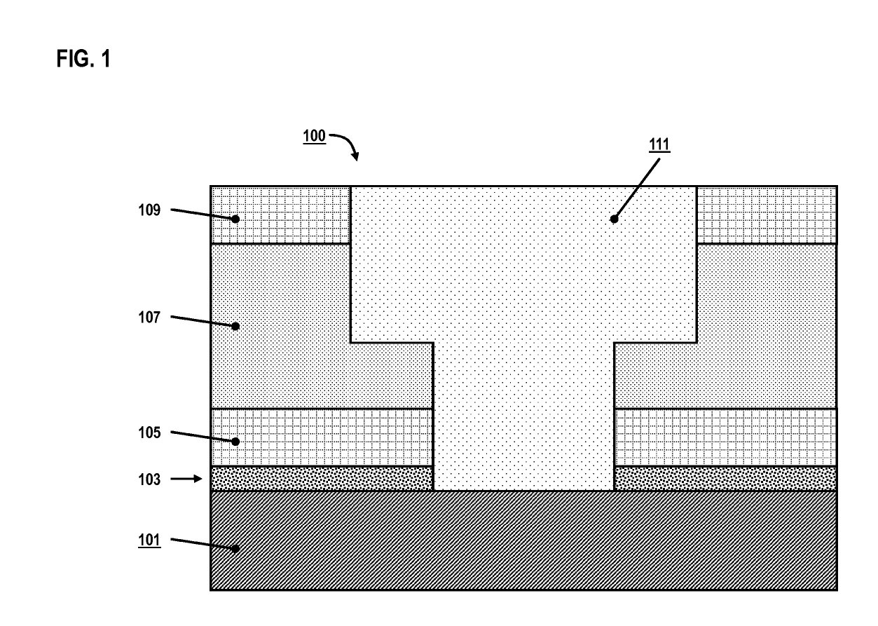

Adverting to FIG. 1, in accordance with an exemplary embodiment, a semiconductor device 100 includes a semiconductor element 101, a silicon carbide material layer 103, a carbon-rich polymeric layer 105, a silicon oxide material layer 107, a carbon-rich polymeric layer 109, and an interconnect 111 including a conductive metal. Interconnect 111 is formed through layers 103 to 109 to connect semiconductor element 101 to a subsequent metal layer (not shown for illustrative convenience).

Semiconductor element 101 in semiconductor device 100 may be, for example, a metal layer such as a metal 7 (M7) or metal 8 (M8) layer. The metal layer in the semiconductor element 101 may, for example, be copper or copper alloy. Alternatively, the metal layer may include aluminum, gold, platinum, etc., and alloys thereof.

Silicon carbide material layer 103 in semiconductor device 100 may include a dielectric capping material including silicon carbide moieties (i.e., Si—C). For example, a silicon carbide material which may be utilized in the silicon carbide material layer 103 is nitrogen-doped silicon carbide (i.e., NBLOK). A function of a silicon carbide material layer, such as silicon carbide material layer 103, is to prevent electromigration (EM) failure of interconnects, such as interconnect 111, which becomes a serious reliability threat when the dimensions of the interconnects approach the nanoscale range. The silicon carbide material layer 103 may for example for formed to thickness of 100 to 5,000 angstroms, e.g. 200 to 1,000 angstroms.

Carbon-rich polymeric layer 105 in semiconductor device 100 may include a low-k dielectric carbon-rich polymeric material including bonded carbons in the polymer (i.e., C—C). For example, carbon-rich polymeric materials which may be utilized for layer 105 include polynorbornene, polybenzocyclobutene, polyimide, polytetrafluoroethylene (i.e., PTFE). The carbon-rich polymeric material is a low-k material, for example having a dielectric constant less than 3.7. The carbon-rich polymeric layer 105 has a thickness of 50 to 500 nm, e.g. 100 to 300 nm.

The carbon-rich polymeric layer 105 imparts favorable mechanical properties to semiconductor device 100. Sources of carbon-rich polymeric materials with favorable mechanical properties are well-known to those having skill in the art.

Carbon-rich polymeric layer 109 in semiconductor device 100 may include the same or different carbon-rich polymeric material utilized in carbon-rich polymeric layer 105 and may have the same or different thickness.

Silicon oxide material layer 107 in semiconductor device 100 may include silicon oxide moieties (i.e., Si—O). For example, the silicon oxide material may include porous organosilicate glass, porous fluorine-doped silicate glass, or a combination thereof. Other silicon oxide materials which may be utilized in the silicon oxide material layer 107 include tetraethyl orthosilicate (i.e., TEOS), fluorine-doped tetraethyl orthosilicate (i.e., FTEOS), phenyltriethyl orthosilicate (i.e., PTEOS) and the like. The silicon oxide material has a dielectric constant between about 3.5 and 4.0, and the silicon oxide layer 107 has a thickness of 900 to 1,500 nm, e.g. 1,000 to 1,300 nm or 1,100 to 1,200 nm.

Interconnect 111 in semiconductor device 100 may include a metal layer including a metal material such as copper or copper alloy. Other metal materials that may be utilized in interconnect 111 include aluminum, gold, platinum, etc., and alloys thereof.

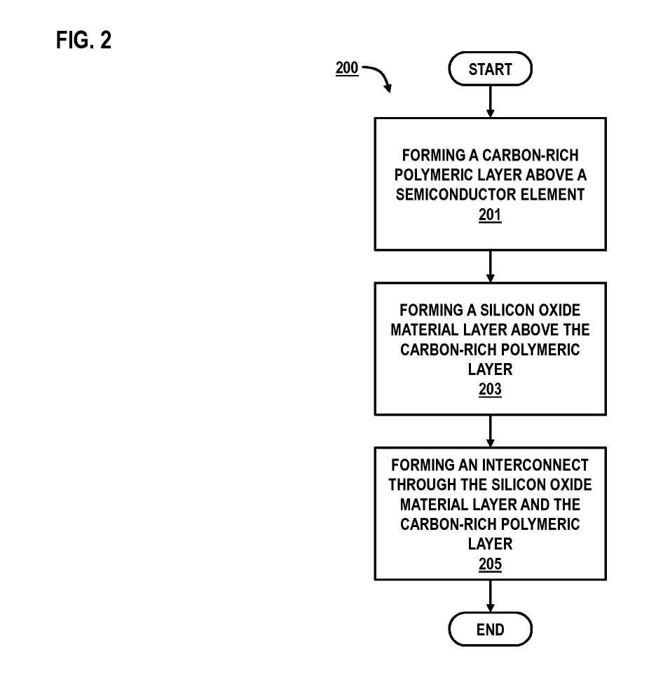

Adverting to FIG. 2, a process 200 is illustrated which may be utilized for preparing semiconductor device 100, according to an exemplary embodiment. The steps of process 200, and other methods described herein, are described by way of example with the semiconductor device 100.

After process start, at step 201, a carbon-rich polymeric layer 105 is formed above a semiconductor element 101. The carbon-rich polymeric layer 105 may include one of polynorbornene, polybenzocyclobutene, polyimide and polytetrafluoroethylene, formed, for example, by deposition. An end capping layer including NBLOK may intervene between the carbon-rich polymeric layer 105 and the semiconductor element 101.

At step 203, a silicon oxide material layer 107 is formed above the carbon-rich polymeric layer 105. The silicon oxide material may include TEOS, FTEOS, and/or PTEOS. Alternatively, the silicon oxide material may include a porous organosilicate glass (i.e., OSG) or a fluorine-doped silicate glass (i.e., FSG).

At step 205, an interconnect 111 is formed through the silicon oxide material layer 107 and the carbon-rich polymeric layer 105. Interconnect 111 may be formed through the layers such as by masking the areas around placement of the interconnect 111 and etching through the layers to form a trench. After etching is performed, a metal material such as copper or copper alloy is laid in the trench thus forming the interconnect 111 through the layers. A metal, such as copper or copper alloy, is deposited into the trench, for example by electrochemical plating, electroless plating, or chemical vapor deposition, to form interconnect 111, as illustrated in FIG. 1. The copper fill may also be accompanied by planarization, such as chemical mechanical polishing (CMP), to remove excess copper or copper alloy.

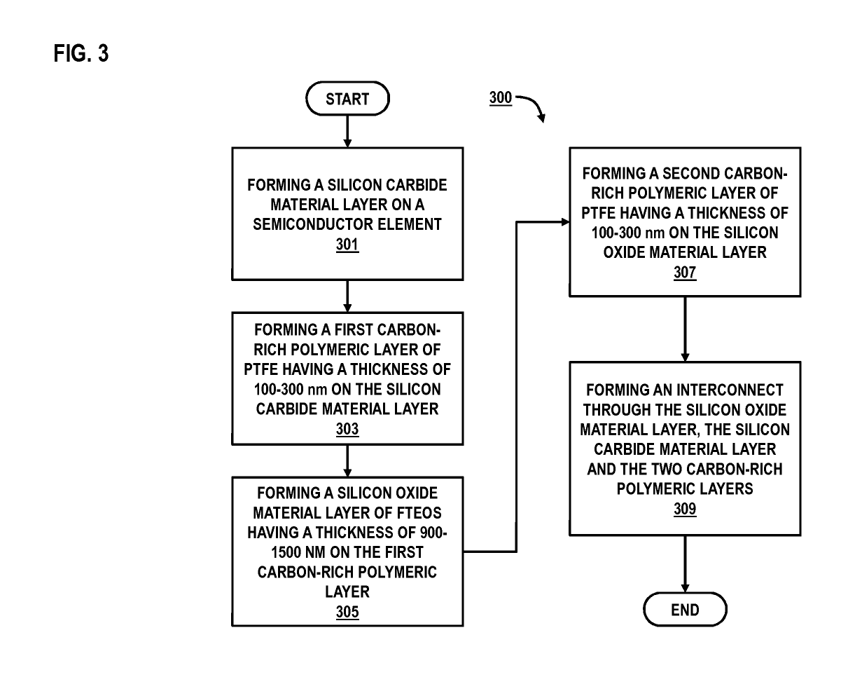

Adverting to FIG. 3, a process 300 is illustrated which may be utilized for preparing semiconductor device 100, according to an exemplary embodiment. The steps of process 300 are described by way of example with the semiconductor device 100.

After process start, at step 301, a silicon carbide material layer 103 is formed above semiconductor element 101. The silicon carbide material layer 103 may include NBLOK.

At step 303, a first carbon-rich polymeric layer 105 is formed on silicon carbide material layer 103. The carbon-rich polymeric layer 105 may include polytetrafluoroethylene and may be formed, such as by deposition, to form a layer having a thickness of 100 to 300 nm.

At step 305, a silicon oxide material layer 107 is formed above the carbon-rich polymeric layer 105. The silicon oxide material may include FTEOS to form a layer having a thickness of 900 to 1500 nm.

At step 307, a second carbon-rich polymeric layer 109 is formed on silicon oxide material layer 107. The carbon-rich polymeric layer 109 may include polytetrafluoroethylene and may be formed, such as by deposition, to form a layer having a thickness of 100 to 300 nm.

At step 309, an interconnect 111 is formed through the carbon-rich polymeric layer 109, the silicon oxide material layer 107, the carbon-rich polymeric layer 105, and the silicon carbide material layer 103. Interconnect 111 may be formed through the layers, such as by masking the areas around placement of the interconnect 111 and etching through the layers to form a trench. A metal, such as copper or copper alloy, is deposited into the trench, for example by electrochemical plating, electroless plating, or chemical vapor deposition, to form interconnect 111, as illustrated in FIG. 1. The copper fill may also be accompanied by planarization, such as CMP, to remove excess copper or copper alloy.

The embodiments of the present disclosure can achieve several technical effects, such as reduced solder fatigue and/or failure as well as reduced underfill delamination attendant upon CPI in flip-chip packaging. The present disclosure enjoys industrial applicability in any of the semiconductor arts. For example, the present disclosure enjoys industrial applicability associated with the designing and manufacturing of any of various types of highly integrated semiconductor devices used in microprocessors, smart phones, mobile phones, cellular handsets, set-top boxes, DVD recorders and players, automotive navigation, printers and peripherals, networking and telecom equipment, gaming systems, and digital cameras.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
forming a carbon-rich polymeric layer above a semiconductor element;
forming a silicon oxide material layer above the carbon-rich polymeric layer; and
forming an interconnect through the silicon oxide material layer and the carbon-rich polymeric layer.

2. The method according to claim 1, further comprising:
forming a silicon carbide material layer above the semiconductor element prior to forming the carbon-rich polymeric layer.

3. The method according to claim 1, further comprising:
forming a second carbon-rich polymeric layer above the semiconductor element prior to forming the interconnect.

4. The method according to claim 3, wherein a combined thickness of the two carbon-rich polymeric layers and the silicon oxide material layer is 1,500 to 1,600 nm.

5. The method according to claim 3, wherein the two carbon-rich polymeric layers comprise one of polynorbornene, polybenzocyclobutene, polyimide and polytetrafluoroethylene.

6. The method according to claim 3, wherein the two carbon-rich polymeric layers comprise polytetrafluoroethylene.

7. The method according to claim 3, wherein the silicon oxide material layer comprises tetraethyl orthosilicate.

8. The method according to claim 3, wherein the silicon oxide material layer comprises fluorine-doped tetraethyl orthosilicate.

9. The method according to claim 3, wherein a thickness of each carbon-rich polymeric layer is 50 to 500 nm.

10. The method according to claim 3, wherein a thickness of each carbon-rich polymeric layer is 100 to 300 nm.

11. A device comprising:
a carbon-rich polymeric layer above a semiconductor element;
a silicon oxide material layer above the carbon-rich polymeric layer; and
an interconnect through the silicon oxide material layer and the carbon-rich polymeric layer.

12. The device according to claim 11, further comprising:
a silicon carbide material layer above the semiconductor element and below the carbon-rich polymeric layer.

13. The device according to claim 11, further comprising:
a second carbon-rich polymeric layer above the semiconductor element.

14. The device according to claim 13, wherein a combined thickness of the two carbon-rich polymeric layers and the silicon-containing material layer is 1,500 to 1,600 nm.

15. The device according to claim 13, wherein the two carbon-rich polymeric layers comprise one of polynorbornene, polybenzocyclobutene, polyimide and polytetrafluoroethylene.

16. The device according to claim 13, wherein the two carbon-rich polymeric layers comprise polytetrafluoroethylene.

17. The device according to claim 13, wherein the silicon oxide material layer comprises tetraethyl orthosilicate.

18. The device according to claim 13, wherein the silicon oxide material layer comprises fluorine-doped tetraethyl orthosilicate.

19. The device according to claim 13, wherein a thickness of each carbon-rich polymeric layer is 50 to 500 nm.

20. A method comprising:
forming a silicon carbide material layer on a semiconductor element;
forming a first carbon-rich polymeric layer on the silicon carbide material layer;
forming a silicon oxide material layer on the first carbon-rich polymeric layer;
forming a second carbon-rich polymeric layer on the silicon oxide material layer; and
forming an interconnect through the silicon carbide material, the first carbon-rich polymeric layer, the silicon oxide material layer, and the second carbon-rich polymeric layer,
wherein a combined thickness of the two carbon-rich polymeric layers and the silicon oxide material layer is 1,500 to 1,600 nm and a thickness of each carbon-rich polymeric layer is 100 to 300 nm, and
wherein the two carbon-rich polymeric layers comprise polytetrafluoroethylene and the silicon oxide material layer comprises fluorine-doped tetraethyl orthosilicate.
